(19) United States
(12) Patent Application Publication
(10) Pub. No.: US 2012/0212220 A1
(43) Pub. Date: Aug. 23, 2012

(54) ELECTRIC JUNCTION BOX AND CURRENT DETECTION DEVICE

(75) Inventor: Susumu Fukuyama, Yokkaichi-shi (JP)

(73) Assignees: AUTONETWORKS TECHNOLOGIES, LTD., YOKKAICHI-SHI, MIE (JP); SUMITOMO ELECTRIC INDUSTRIES, LTD., OSAKA-SHI, OSAKA (JP); SUMITOMO WIRING SYSTEMS, LTD., YOKKAICHI-SHI, MIE (JP)

(21) Appl. No.: 13/504,047

(22) PCT Filed: Nov. 8, 2010
(86) PCT No.: PCT/JP2010/069783

§ 371 Date: Apr. 25, 2012

(30) Foreign Application Priority Data
Nov. 6, 2009 (JP) 2009-254961

(51) Int. Cl. G01R 33/04

(52) U.S. Cl. 324/253

(57) ABSTRACT

An electric junction box includes a current detection device that has a magneto-electric conversion element and a magnetic core with a gap portion where the magneto-electric conversion element is disposed to detect magnetic flux occurring on the magnetic core as a current. The magnetic core has a conductor insertion portion through which the conductor subject to current detection is inserted. The conductor has a terminal portion to be connected to any other members, a round-shaped cross-sectional portion whose cross section perpendicular to an axial direction of the conductor is shaped like a circle and whose cross-sectional diameter is set equal to or less than an inner diameter of the conductor insertion portion, and a thin wall portion whose thickness is set equal to or less than a width size X of the gap portion.

### TECHNICAL FIELD

The present invention relates to an electric junction box and a current detection device.

### BACKGROUND ART

An electric junction box which is mounted on a vehicle etc. includes a current detection device in some cases (see, for example, Patent Document 1). Patent Document 1 describes a current sensor in which a magnetic core, a bus bar (conductor) which is inserted into an insertion portion in the magnetic core to be subject to current detection, and a magneto-electric conversion element which is disposed to a gap portion of the magnetic core to detect magnetic flux occurring due to a current flowing through the bus bar as a current are housed in a case.

The bus bar is disposed so as to project out from the case so that its end portion projecting from the case may be fitted with a terminal portion to be connected with a battery or an inverter.

Patent Document 1: Japanese Patent Application Laid-Open No. 2002-243768

### DISCLOSURE OF THE PRESENT INVENTION

Generally, the size of the terminal portion of a conductor provided in an electric junction box is determined according to the amount of a current flowing through the conductor. That is, if the current flowing through the bus bar increases, it becomes necessary to increase the width or thickness of the terminal portion of the bus bar. For example, the bus bar described in Patent Document 1 is shaped like a flat plate as a whole and, therefore, is larger as a whole as the width or thickness of the terminal portion increase. If the bus bar becomes larger, the magnetic core through which the bus bar is inserted needs to be larger, and if the magnetic core becomes larger, the current detection device also becomes larger. As a result, the electric junction box fitted with the current detection device also becomes larger.

The present invention has been developed in view of the circumstances above, and it is an object of the present invention to miniaturize an electric junction box and a current detection device.

To solve the problems, the present invention provides an electric junction box fitted with a current detection device, in which the current detection device includes a magneto-electric conversion element and a magnetic core provided with a gap portion in which the magneto-electric conversion element is disposed, to detect magnetic flux occurring on the magnetic core as a current; the magnetic core has a conductor insertion portion into which the conductor subject to current detection can be inserted; and the conductor includes a terminal portion to be connected to any other members, a round-shaped cross-sectional portion whose cross section perpendicular to an axial direction of the conductor is shaped like a circle and whose cross-sectional diameter is set equal to or less than an inner diameter of the conductor insertion portion, and a thin wall portion whose thickness is set equal to or less than a width size of the gap portion.

In the present invention, when attaching the conductor to the magnetic core, first the thin wall portion of the conductor is inserted to the gap portion of the magnetic core. According to the present invention, since the thin wall portion of the conductor is set equal to or less than the width size of the gap portion, the thin wall portion of the conductor can be inserted into the gap portion of the magnetic core smoothly.

Next, the conductor or the magnetic core is moved so that the conductor insertion portion in the magnetic core may be disposed at the round-shaped cross-sectional portion of the conductor. In the present invention, the conductor has the round-shaped cross-sectional portion whose cross section is circular in shape and whose cross-sectional diameter is set equal to or less than the inner diameter of the conductor insertion portion, so that even if the terminal portion has a size that suits the amount of the current, the conductor can be inserted into the conductor insertion portion in the magnetic core.

Further, in the present invention, the conductor includes a portion having a round-shaped cross-section separately from the terminal portion, so that irrespective of the size of the terminal portion, it is possible to arbitrarily set the size, the shape, and the setting position of the portion to be inserted into the gap in the magnetic core with respect to the axial direction of the conductor. In this case, by making the portion of the conductor to be inserted into the magnetic core round-shaped in cross section, the conductor insertion portion in the magnetic core can be minimized.

Therefore, according to the present invention, by providing the conductor with the round-shaped cross-sectional portion whose cross-sectional shape is circular, it is possible to minimize the conductor insertion portion in the magnetic core, thereby minimizing the current detection device.

According to the present invention, it is possible to minimize the electric junction box and the current detection device.

### BRIEF DESCRIPTION OF DRAWINGS

FIG. 1 is a schematic diagram schematically showing one portion of an electric junction box of a first embodiment;

FIG. 2 is a partial cross-sectional view of a conductor in a direction perpendicular to an axial direction;

FIG. 3 is a front view showing one portion of the conductor before a magnetic core is inserted therethrough;

FIG. 4 is a partial perspective view explaining procedures for attaching the magnetic core to the conductor;

FIG. 5 is a partial side view explaining the procedures for attaching the magnetic core to the conductor;

FIG. 6 is a partial perspective view of the conductor through which the magnetic core is inserted;

FIG. 7 is a partial perspective view of the conductor attached to the electric j unction box of a second embodiment; and

FIG. 8 is a partial perspective view explaining procedures for inserting the conductor into the magnetic core.

### EXPLANATION OF SYMBOLS

1: Electric junction box

10: Current detection device

11: Magnetic core

12: Gap portion

13: Conductor insertion portion

14: Magneto-electric conversion element

21: Terminal portion

22: Round-shaped cross-sectional portion

23: Thin wall portion

30: Conductor

31: Terminal portion

32: Covered wire (round-shaped cross-sectional portion)

32A: Covering material

33: Wire (thin wall portion)

33A: Stranded wire

R: Diameter (of round-shaped cross-sectional portion)

X: Width size (of gap portion)

Y: Inner diameter (of conductor insertion portion)

### BEST MODE FOR CARRYING OUT INVENTION

### First Embodiment

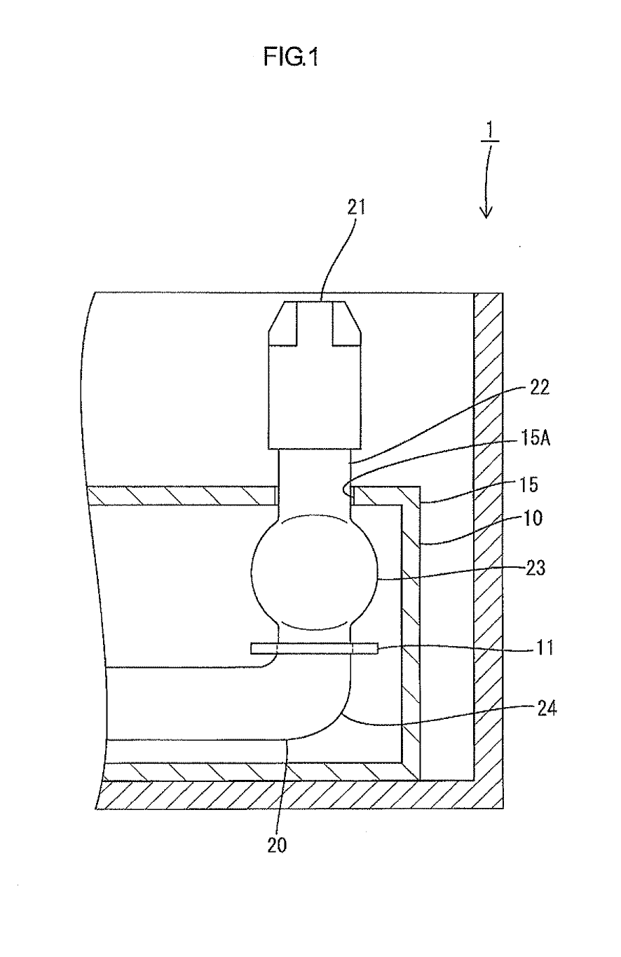

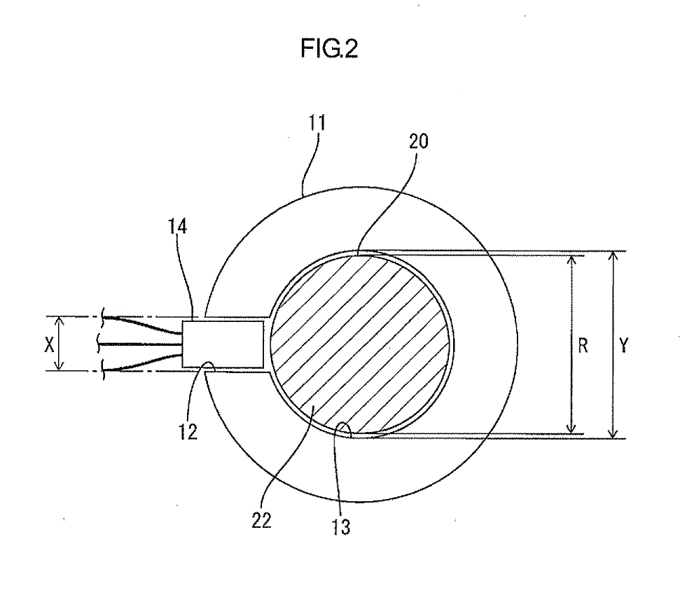

A first embodiment of the present invention will be described with reference to FIGS. 1 to 6. An electric junction box 1 of the present embodiment includes a current detection device 10 that detects a current flowing through a conductor 20. A magnetic core 11, a magneto-electric conversion element 14 disposed in the magnetic core 11, and the conductor 20 are housed in a case 15 of the current detection device 10 (see FIGS. 1 and 2).

The case 15 of the current detection device 10 is shaped like a box as shown in FIG. 1 and has an insertion hole 15A formed at an upper side of the case 15, through which the conductor 20 projects out.

The magnetic core 11 is shaped roughly like a letter C and has a gap portion 12 and a conductor insertion portion 13 through which the conductor 20 is inserted as shown in FIG. 2. In the gap portion 12 of the magnetic core 11, a magneto-electric conversion element 14 for detecting magnetic flux is disposed.

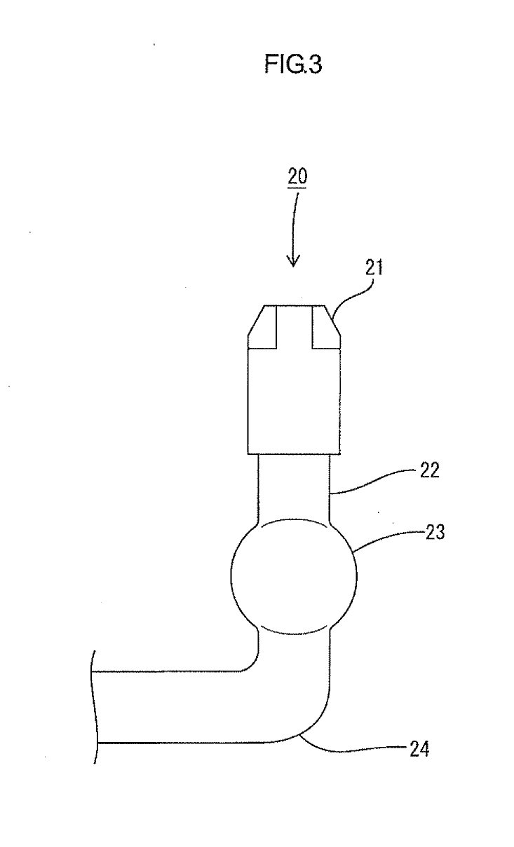

As shown in FIG. 3, the conductor 20 is shaped roughly like a letter L as a whole and has, at its upper end portion, a terminal portion 21 which is connected to any other member (not shown) such as a battery or an inverter and, below the terminal portion 21, a round-shaped cross-sectional portion 22 whose cross section is shaped like a circle perpendicular to an axial direction of the conductor 20 (see FIG. 2). The size of the terminal portion 21 is determined by the amount of a current flowing through the conductor 20.

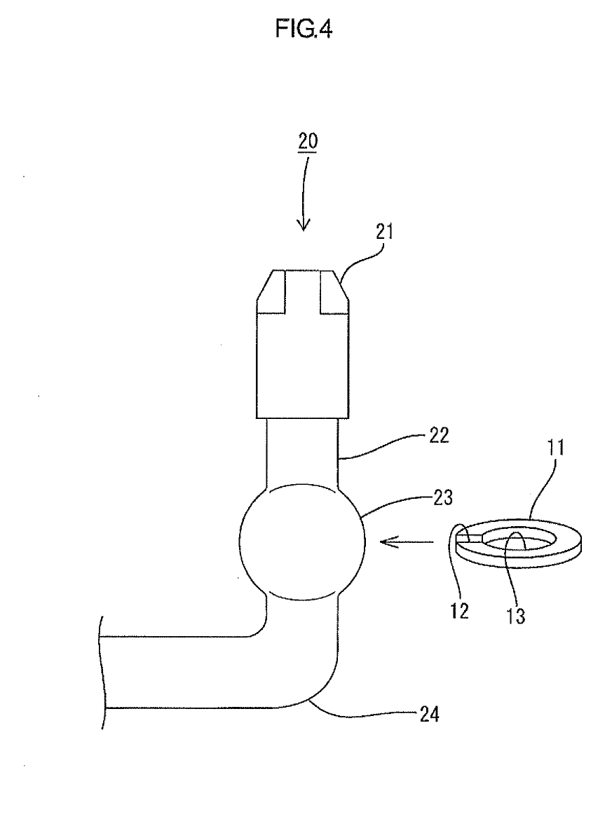

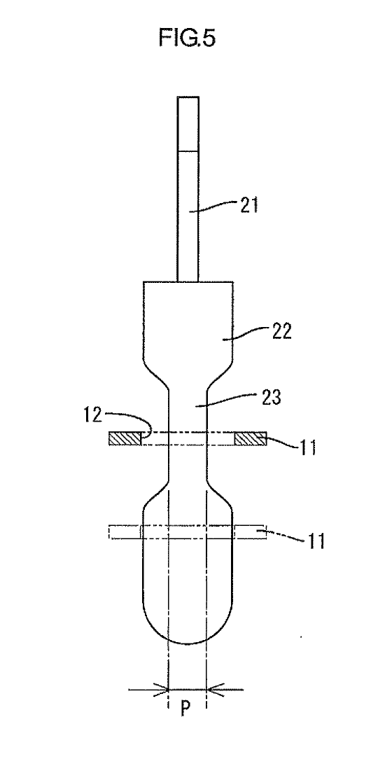

The round-shaped cross-sectional portion 22 is formed of a round bar made of a conductive material such as copper and has its cross-sectional diameter R set equal to or less than an inner diameter Y of the conductor insertion portion 13 of the magnetic core 11. A round portion 23 provided slightly above a bent portion 24 of the round-shaped cross-sectional portion 22 which is bent like a letter L is the thin wall portion 23 which is formed by deforming the round bar and reducing its thickness (see FIG. 4). A thickness P of the thin wall portion 23 is set equal to or less than a width size X of the gap portion 12 so that the thin wall portion 23 can be inserted to the gap portion 12 smoothly (see FIG. 5).

Next, a description will be briefly given of a method of assembling the current detection device 10 to the electric junction box 1. The round bar whose cross-sectional diameter is equal to or less than the inner diameter Y of the conductor insertion portion 13 in the magnetic core 11 is deformed by press working, to form the thin wall portion 23 whose one portion has a thickness equal to or less than the width size of the gap portion 12 of the magnetic core 11. The round bar having the thin wall portion is bent into a predetermined shape and the terminal portion 21 is connected to an end portion of the round bar by a method of welding etc., thereby obtaining the conductor 20. In this case, the process to form the round bar into the predetermined shape and the step of connecting the terminal portion 21 maybe performed before forming the thin wall portion 23.

The conductor 20 manufactured in such a manner is fitted with the magnetic core 11 along the following procedures. First, as shown in FIG. 4, the thin wall portion 23 of the conductor 20 is inserted through the gap portion 12 of the magnetic core 11. In the present embodiment, the thin wall portion 23 of the conductor 20 has a thickness set equal to or less than the width size X of the gap portion 12 and, therefore, can be inserted through the gap portion 12 of the magnetic core 11 smoothly.

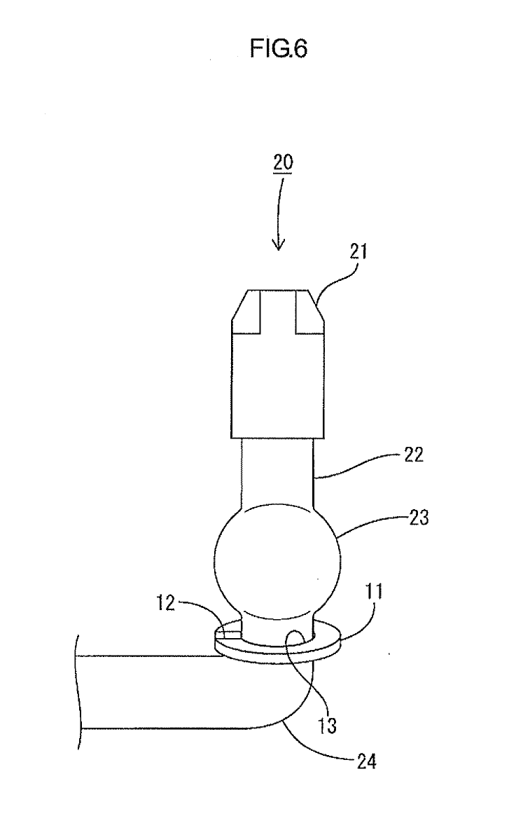

Next, the conductor 20 or the magnetic core 11 is moved so that the conductor insertion portion 13 in the magnetic core 11 is disposed at the round-shaped cross-sectional portion 22 lower than the thin wall portion (see FIGS. 5 and 6). In the present embodiment, the cross-sectional diameter R of the round-shaped cross-sectional portion 22 is set equal to or less than the inner diameter Y of the conductor insertion portion 13, so that even if the terminal portion 21 is made large to accommodate the amount of a current flowing through the conductor 20, the conductor 20 can be inserted into the conductor insertion portion 13 in the magnetic core 11.

After disposing the conductor 20 fitted with the magnetic core 11 to the predetermined position in the case 15, the magneto-electric conversion element 14 is attached to the gap portion 12 of the magnetic core 11. Next, the case 15 mounted with the conductor 20 is disposed to a predetermined position in the electric junction box 1, the current detection device 10 is assembled to the electric junction box 1.

Next, a description will be given of the effects of the present embodiment. In the present embodiment, the conductor 20 is provided with the round-shaped cross-sectional portion 22 having a circular cross section separately from the terminal portion 21. Specifically, the portion to be inserted into the magnetic core 11 is separated from the terminal portion 21, so that its size and shape can be set irrespective of the size of the terminal portion 21. In this case, if the portion of the conductor 20 to be inserted into the magnetic core 11 is circular in cross section, the conductor insertion portion 13 in the magnetic core 11 can be minimized. Therefore, according to the present embodiment, the size of the conductor insertion portion 13 in the magnetic core 11 can be minimized, thereby miniaturizing the magnetic core 11 and the current detection device 10.

Further, according to the present embodiment, a portion of the round bar is deformed and thinned by the method of press working to form the thin wall portion 23 of the round-shaped cross-sectional portion 22, so that the thin wall portion 23 can be formed easily.

### Second Embodiment

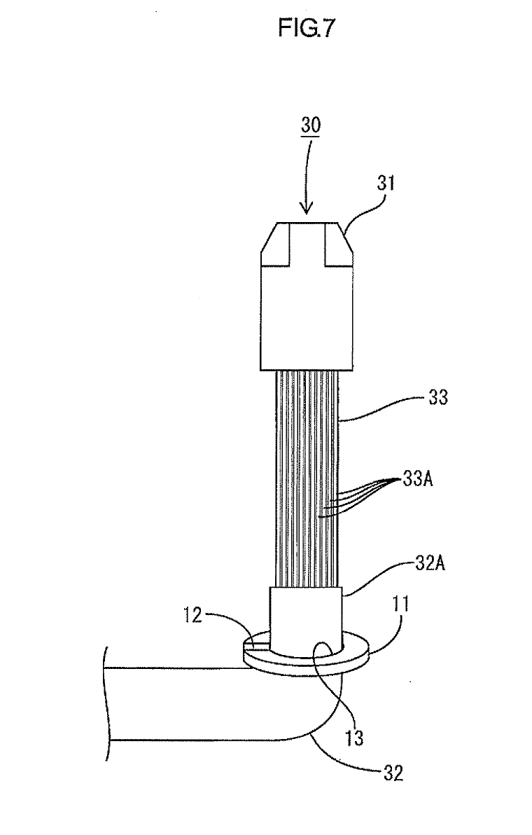

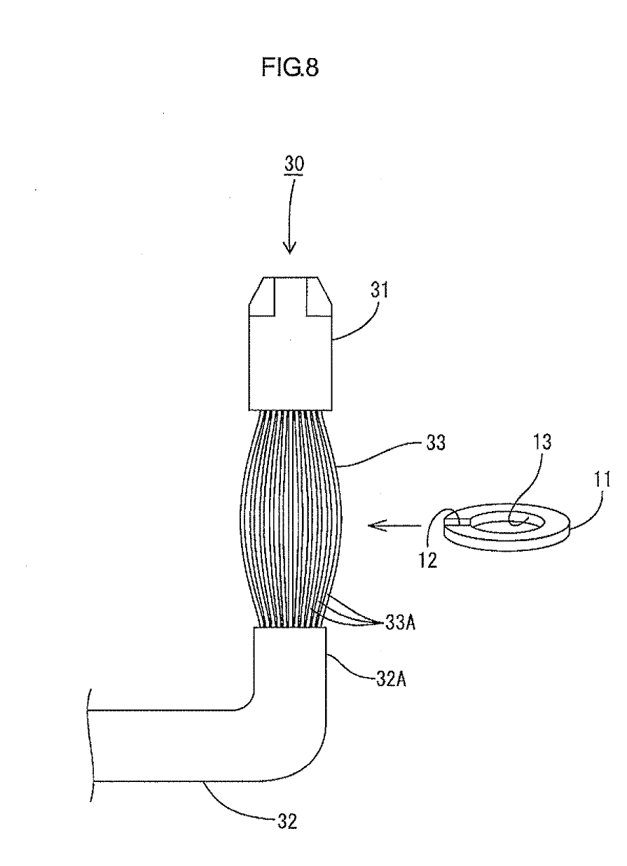

Next, a second embodiment of the present invention will be described with reference to FIGS. 7 and 8. In the present embodiment, the configuration of a conductor 30 attached to an electric junction box 1 is different from that of the first embodiment. The other components are almost the same as those of the first embodiment, so that identical reference numerals are given to identical components in the first and second embodiments, and repetitive description on the identical components will be omitted.

The electric junction box 1 of the present embodiment is fitted with the conductor 30 which includes a terminal portion 31 and a covered wire 32 in which a stranded wire 33A is covered by a covering material 32A at an upper end and a lower end of a wire 33 formed of the stranded wire 33A respectively as shown in FIG. 7.

The cross section of the covered wire 32 perpendicular to the axial direction is circular in shape, and the portion 32 formed of this covered wire corresponds to a round-shaped cross-sectional portion 32 of the present invention. A diameter R of the cross section of the covered wire 32 is set equal to or less than an inner diameter Y of a conductor insertion portion 13 in a magnetic core 11. The covering material 32A of the covered wire 32 includes an enamel-made covering material or a resin-made covering material.

The portion 33 formed of the wire, which corresponds to the thin wall portion 33, is to be inserted through a gap portion 12 of the magnetic core 11 after being loosened so that the portion 33 may be thinned equal to or less than a width size X of the gap portion 12 of the magnetic core 11.

Next, a description will be briefly given of a method of assembling the magnetic core 11 to the conductor 30. The covering material 32A of a portion of the covered wire 32 whose cross-sectional diameter is equal to or less than the inner diameter Y of the conductor insertion portion 13 in the magnetic core 11 is peeled of f and removed to expose the stranded wire 33A. Next, the covered wire 32 is bend into a predetermined shape, to connect the terminal portion 31 to an end of the exposed stranded wire 33A by the method of welding etc. In this case, the process of connecting the terminal portion 31 may be performed before bending the covered wire 32.

The conductor 30 manufactured in such a manner is attached to the magnetic core 11 by the following procedure. First, as shown in FIG. 8, the stranded wire 33A is loosened so as to be thinned equal to or less than the width size of the gap portion 12 of the magnetic core 11 so that the thin wall portion 33 may be formed, which thin wall portion 33 is then inserted into the gap portion 12 of the magnetic core 11. In the present embodiment also, the thin wall portion 33 of the conductor 30 is set equal to or less than a thickness of the width size X of the gap portion 12, so that the thin wall portion 33 of the conductor 30 can be inserted into the gap portion 12 of the magnetic core 11 smoothly.

Next, the conductor 30 or the magnetic core 11 is moved so that the conductor insertion portion 13 in the magnetic core 11 may be disposed to the round-shaped cross-sectional portion 32 below the thin wall portion 33, thereby attaching the magnetic core 11 to the conductor 30 (see FIG. 7).

Next, a description will be given of effects of the present embodiment. According to the present embodiment, the thin wall portion 33 is formed of a wire group of the stranded wires 33A, so that the thin wall portion 33 can be inserted into the gap portion 12 of the magnetic core 11 easily, thereby improving the efficiency of inserting the conductor 30 into the magnetic core 11.

Further, according to the present embodiment, the round-shaped cross-sectional portion 32 is formed of the covered wire 32 including the stranded wire 33A and the covering material 32A and the thin wall portion 33 is formed by peeling off the covering material 32A from a portion of the covered wire 32 and removing it, so that the thin wall portion 33 can be formed easily.

### First Modification Example

A description will be given of a first modification example of the second embodiment. Although the second embodiment includes the conductor 30 having the thin wall portion 33 formed by removing the covering material 32A from a portion of the covered wire 32, the present modification example is different from the second embodiment in that the thin wall portion 33 includes the conductor 30 formed by connecting the terminal portion 31 by the method of welding etc. to one end of a wire (wire not covered by the covering material) formed of the stranded wire 33A and connecting the covered wire 32 to the other end of the wire by the method of welding etc. The other configurations are almost the same as those of the second embodiment.

### Other Embodiments

The present invention is not limited to the embodiment described above with reference to the drawings and may include, for example, the following embodiments in its technical scope.
(1) Although in the first embodiment, the thin wall portion has been provided by deforming a portion of the round bar and reducing its thickness, the thin wall portion may be made of any other material than the round bar forming the round-shaped cross-sectional portion and may be connected to a predetermined position on the round-shaped cross-sectional portion.

### Means for Solving Problems

To solve the problems, the present embodiment provides an electric junction box fitted with a current detection device, in which the current detection device has a magneto-electric conversion element and a magnetic core with a gap portion in which the magneto-electric conversion element is disposed, to detect magnetic flux occurring on the magnetic core as a current; the magnetic core has a conductor insertion portion configured to insert the conductor subject to current detection thererthrough; and the conductor has a terminal portion to be connected to any other members, a round-shaped cross-sectional portion whose cross section perpendicular to an axial direction of the conductor is shaped like a circle and whose cross-sectional diameter is set equal to or less than an inner diameter of the conductor insertion portion, and a thin wall portion whose thickness is set equal to or less than a width size of the gap portion.

In the present embodiment, when attaching the conductor to the magnetic core, first the thin wall portion of the conductor is inserted to the gap portion of the magnetic core. According to the present embodiment, since the thin wall portion of the conductor is set equal to or less than the width size of the gap portion, the thin wall portion of the conductor can be inserted into the gap portion of the magnetic core smoothly.

Next, the conductor or the magnetic core is moved so that the conductor insertion portion in the magnetic core maybe disposed at the round-shaped cross-sectional portion of the conductor. In the present embodiment, the conductor has the round-shaped cross-sectional portion whose cross section is circular in shape and whose cross-sectional diameter is set equal to or less than the inner diameter of the conductor insert ion portion, so that even if the terminal portion has a size that matches the amount of the current, the conductor can be inserted into the conductor insertion portion in the magnetic core.

Further, in the present embodiment, the conductor is fitted with a round-shaped cross-sectional portion separately from the terminal portion, so that irrespective of the size of the terminal portion, it is possible to arbitrarily set the size, the shape, and the setting position of the portion to be inserted into the gap in the magnetic core with respect to the axial direction of the conductor. In this case, by making the portion of the conductor to be inserted into the magnetic core round-shaped in cross section, the conductor insertion portion in the magnetic core can be minimized.

Therefore, according to the present embodiment, by providing the conductor with the round-shaped cross-sectional portion whose cross-sectional shape is circular, it is possible to minimize the conductor insertion portion in the magnetic core, thereby minimizing the current detection device.

The present embodiment may have the following configuration.

The round-shaped cross-sectional portion may be formed of a round bar made of a conductive material and the thin wall portion may be formed by deforming a portion of the round bar and reducing its thickness. With this configuration, the thin wall portion can be formed easily by deforming a portion of the round bar by the method of press working etc.

The thin wall portion may be formed of a wire group configured by stranded wires. With this configuration, the thin wall portion can be easily inserted into the gap portion of the magnetic core, so that the efficiency of inserting the conductor into the magnetic core is improved.

In this configuration, the round-shaped cross-sectional portion may be formed of a covered wire including the stranded wire and a covering material which covers the stranded wire and the thin wall portion may be formed by removing the covering material from a portion of the covered wire. With this configuration, the thin wall portion can be formed easily by removing the covering material from the covered wire.

1. An electric junction box comprising:
a current detection device; and
a conductor, wherein:
the current detection device includes a magneto-electric conversion element and a magnetic core including a gap portion in which the magneto-electric conversion element is disposed, to detect magnetic flux occurring on the magnetic core as a current;
the magnetic core has a conductor insertion portion configured to insert the conductor subject to current detection therethrough; and
the conductor includes a terminal portion to be connected to any other members, a round-shaped cross-sectional portion whose cross section perpendicular to an axial direction of the conductor is shaped like a circle and whose cross-sectional diameter is set equal to or less than an inner diameter of the conductor insertion portion, and a thin wall portion whose thickness is set equal to or less than a width size of the gap portion.

2. The electric junction box according to claim 1, wherein: the round-shaped cross-sectional portion is formed of a round bar made of a conductive material; and
the thin wall portion is formed by deforming a portion of the round bar and reducing its thickness.

3. The electric junction box according to claim 1, wherein the thin wall portion is formed of a wire group including stranded wires.

4. The electric junction box according to claim 3, wherein the round-shaped cross-sectional portion includes a covered wire including the stranded wire and a covering material which covers the stranded wire and the thin wall portion is formed by removing the covering material from a portion of the covered wire.

5. A current detection device comprising:
a magneto-electric element; and
a magnetic core with a gap portion in which the magneto-electric conversion element is disposed, wherein:
the current detection device detects magnetic flux occurring on the magnetic core as a current;
the magnetic core has a conductor insertion portion configured to insert the conductor subject to current detection therethrough; and
the conductor includes a terminal portion to be connected to any other members, a round-shaped cross-sectional portion whose cross section perpendicular to an axial direction of the conductor is shaped like a circle and whose cross-sectional diameter is set equal to or less than an inner diameter of the conductor insertion portion, and a thin wall portion whose thickness is set equal to or less than a width size of the gap portion.

6. The current detection device according to claim 5, wherein: the round-shaped cross-sectional portion is formed of a round bar made of a conductive material; and
the thin wall portion is formed by deforming a portion of the round bar and reducing its thickness.

7. The current detection device according to claim 5, wherein the thin wall portion is formed of a wire group including stranded wires.

8. The current detection device according to claim 7, wherein the round-shaped cross-sectional portion is formed of a covered wire including the stranded wire and a covering material which covers the stranded wire and the thin wall portion is formed by removing the covering material from a portion of the covered wire.
